(19) United States
(12) Patent Application Publication
(10) Pub. No.: US 2012/0098046 A1
(43) Pub. Date: Apr. 26, 2012

(54) ELECTROSTATIC DISCHARGE PROTECTION DEVICE

(75) Inventor: Kilho Kim, Icheon-si (KR)

(73) Assignee: BauaBTech

(21) Appl. No.: 13/277,256

(22) Filed: Oct. 20, 2011

(30) Foreign Application Priority Data
Oct. 20, 2010 (KR) 10-2010-0102205

(51) Int. Cl. H01L 27/092

(52) U.S. Cl. 257/296; 257/355; 257/E27.062

(57) ABSTRACT

An ESD protection device is provided. The ESD protection device includes a first group of electrostatic discharge protection devices connected to a first terminal and including at least one of an LORGGR and an HORGGR, and a second group of electrostatic discharge protection devices connected in series to the first group of electrostatic discharge protection devices and a second terminal and including at least one of a GGNMOS, a GGPMOS and a diode.

### FIELD OF TECHNOLOGY

The present disclosure relates to electrostatic discharge protection devices and, more particularly, to an electrostatic discharge protection device for high voltage operation.

### BACKGROUND

Generally, in fabrication of microchips, it is an essential aspect of chip design to provide a circuit for protection of a microchip from electrostatic discharge (ESD) stress. Typically, chip failure occurs when static electricity caused by contact between an external pad of a microchip and a charged human body or machine is discharged to a core circuit or when accumulated static electricity flows to the core circuit. Here, a device used to protect the core circuit from such chip failure is referred to as an electrostatic discharge protection device. The electrostatic discharge protection device is generally disposed between the external pad and the core circuit.

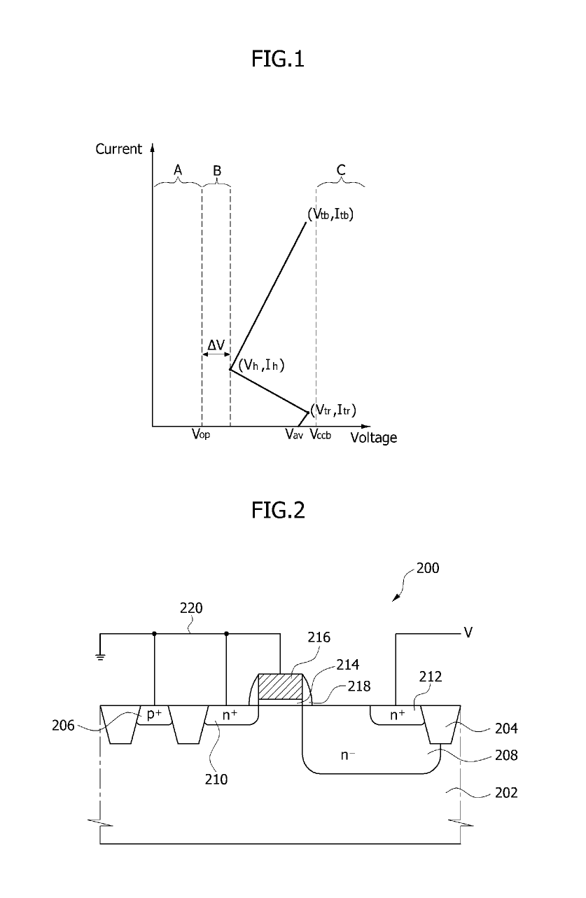

FIG. 1 is a graphical representation of fundamental requirements of an ESD protection device for a microchip. In FIG. 1, “A” indicates an operating range of the microchip, “B” indicates a safety margin, and “C” indicates a breakdown region. Referring to FIG. 1, the ESD protection device must prevent current flow therethrough upon application of voltage less than or equal to an operating voltage Vop during normal operation of the microchip. In order to satisfy this requirement, the avalanche breakdown voltage Vav and the triggering voltage Vtr of the ESD protection device at a triggering point Pt must be greater than the operating voltage Vop of the microchip during normal operation.

Further, the ESD protection device must provide sufficient protection to a core circuit of the microchip when the microchip is subjected to electrostatic discharge stress. Thus, when electrostatic current flows to the microchip, it must be discharged to the outside through the ESD protection device before flowing into the core circuit. To satisfy this requirement, the triggering voltage Vtr of the ESD protection device must be sufficiently lower than the core circuit breakdown voltage Vccb of the microchip.

Further, the ESD protection device must be prevented from abnormal operation resulting from a latch-up phenomenon. Generally, an efficient ESD protection device exhibits a resistance snapback characteristic wherein on-resistance of the ESD protection device is reduced after the device is triggered. Such a resistance snapback characteristic is exhibited as a voltage snapback phenomenon wherein the corresponding voltage is lowered, despite an increase in current flowing through the ESD protection device. Here, if the snapback phenomenon becomes too severe, the ESD protection device suffers a latch-up phenomenon which allows excess current to flow through the ESD protection device, thereby causing thermal breakdown of the microchip, even when the microchip is normally operated. To prevent the ESD protection device from performing abnormal operation resulting from the lath-up phenomenon, the snapback holding voltage Vh of the ESD protection device must be greater than the operating voltage of the microchip by a sufficient safety margin (Δ V). Alternatively, the triggering current Itr must be sufficiently greater than a certain value, for example, 100 mA.

Further, when the ESD protection device adopts a multi-finger structure, it is necessary to guarantee uniform operation of the respective fingers of the ESD protection device. In other words, other fingers must also be triggered to cooperatively discharge ESD current before a certain finger is triggered and suffers thermal breakdown. To satisfy this requirement, the thermal breakdown voltage Vtb of the ESD protection device must be greater than or at least similar to the triggering voltage Vtr. In addition, the ESD protection device must ensure sufficient immunity to electrostatic discharge current while having as small a size as possible. Further, when electrostatic current flows into the ESD protection device, it must operate at as low a voltage as possible. Thus, the ESD protection device must start to operate as fast as possible upon detection of inflow of electrostatic current.

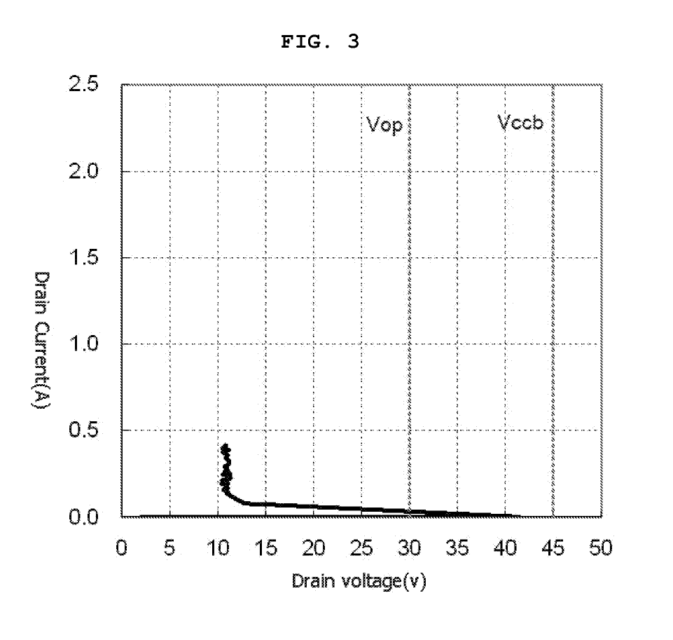

Conventionally, an N-type MOSFET having a double diffused drain, that is, a double diffused drain N-type MOSFET (DDDNMOS), is used as a basic element of the ESD protection device. Referring to FIG. 2, the DDDNMOS is formed on a substrate 202 having an active area defined by a trench isolation layer 204. The substrate 202 has a p-conductive type region, and, when an n-conductive type substrate is used, the substrate may be provided with a p−type well region. The substrate 202 is formed at an upper activation region thereof with a p+type impurity region 206, an n−type drift region 208, and an n+type impurity regions 210, 212. The n+type impurity region 210 is a source region. The n+ impurity region 212 is a drain region and is disposed on the n−type drift region 208. On a channel region between the n+type impurity region 210 and the n−type drift region 208, a gate insulation layer 214 and a gate conductive layer 216 are sequentially disposed. Gate spacer layers 218 are disposed on side surfaces of the gate insulation layer 214 and the gate conductive layer 216. Since such DDDNMOS structure enables sufficient reduction of impurity density for the n−type drift region 208 and the p−type substrate 202 (or p−type well region) adjoining each other, it is possible to achieve a desired high avalanche breakdown voltage.

In order to use such a DDDNMOS as an ESD protection device 200, the p+type impurity region 206, the n+type impurity region 210 and the gate conductive layer 216 are connected to ground through a first wire 220. Further, the n+type impurity region 212 is connected to an external voltage terminal V. The ESD protection device 200 including the DDDNMOS with the gate connected to ground is referred to as a gate grounded double diffused drain N-type MOSFET (GGDDDNMOS). The GGDDDNMOS substantially prevents electric current from flowing therethrough when voltage applied thereto through the external voltage terminal V is lower than the avalanche breakdown voltage. On the other hand, when the voltage applied thereto is higher than the avalanche breakdown voltage, that is, when electrostatic voltage is applied thereto, a large amount of current flows between the n+type impurity regions 210, 212, thereby preventing electrostatic discharge current from flowing to other portions of the device.

In such a GGDDDNMOS, however, a current path is mainly formed on the surface of the device, thereby causing a significant deterioration in the ability of the GGDDDNMOS to cope with ESD stress current. Specifically, a surface temperature of the device sharply rises even at low current, causing thermal breakdown on the surface of the device at low current. That is, as can be seen from the voltage-current characteristics of the GGDDDNMOS shown in FIG. 3, the GGDDDNMOS has low ability in coping with electrostatic current and a lower thermal breakdown voltage than the triggering voltage thereof, thereby making it difficult to achieve uniform operation of the respective fingers of the multi-finger structure.

### SUMMARY

The present disclosure provides improved electrostatic discharge protection devices that may have high avalanche breakdown voltage and cope with a large amount of electrostatic discharge current while achieving uniform operation of respective fingers in a multi-finger structure.

According to an aspect of the present disclosure, an electrostatic discharge (ESD) protection device includes: a first group of electrostatic discharge protection devices connected to a first terminal and including at least one of an LORGGR and an HORGGR, and a second group of electrostatic discharge protection devices connected in series to the first group of electrostatic discharge protection devices and a second terminal and including at least one of a GGNMOS, a GGPMOS and a diode.

In one embodiment, the HORGGR includes: a p−type well region and an n−type well region disposed in contact with each other at one side thereof; an n−type drain region disposed on a contact side between the p−type well region and the n−type well region; an n−type source region disposed in the p−type well region to be separated from the n−type drain region by a distance corresponding to a channel region; a gate electrode layer disposed on the channel region with a gate insulation layer interposed therebetween; a p−type anode region disposed inside the n−type well region; a plurality of conductive layers for a coupling resistor disposed above the p−type well region and separated from each other; a capacitor including an impurity region disposed inside the n−type well region and a capacitor electrode layer disposed above the n−type well region with an insulation layer interposed therebetween; a first wire connecting the n−type source region and a conductive layer disposed at one end of the device among the plurality of conductive layers to a cathode; a second wire connecting a conductive layer disposed at the other to end of the device among the plurality of conductive layers, the gate electrode layer, and the capacitor electrode layer to one another; and a third wire connecting the p−type anode region to an anode.

The capacitor may be disposed between the n−type drain region and the p−type anode region.

The capacitor may be disposed at one side of the p−type anode region opposite the n−type drain region.

The HORGGR may further include: a p-n diode including a p−type anode junction region connected to the n−type source region and an n−type cathode junction region connected to the cathode.

A plurality of p-n diodes each including the p−type anode junction region connected to the n−type source region and the n−type cathode junction region connected to the cathode may be serially arranged.

The HORGGR may include a MOS transistor having a drain connected to an anode and a source connected to a cathode; a capacitor connected at one end thereof to a gate of the MOS transistor and at the other end thereof to the anode; and a resistor connected at one end thereof to the gate of the MOS transistor and the one end of the capacitor, and connected at the other end thereof to the cathode.

The HORGGR may further include a diode for forward operation between the source of the MOS transistor and the cathode.

### BRIEF DESCRIPTION

The above and other aspects, features and advantages of the present disclosure will become apparent from the following description of exemplary embodiments given in conjunction with the accompanying drawings, in which:

FIG. 1 is a graphical representation of fundamental conditions for an ESD protection device;

FIG. 2 is a sectional view of a GGDDDNMOS provided as an ESD protection device;

FIG. 3 is a graphical representation of voltage-current characteristics of the GGDDDNMOS of FIG. 2;

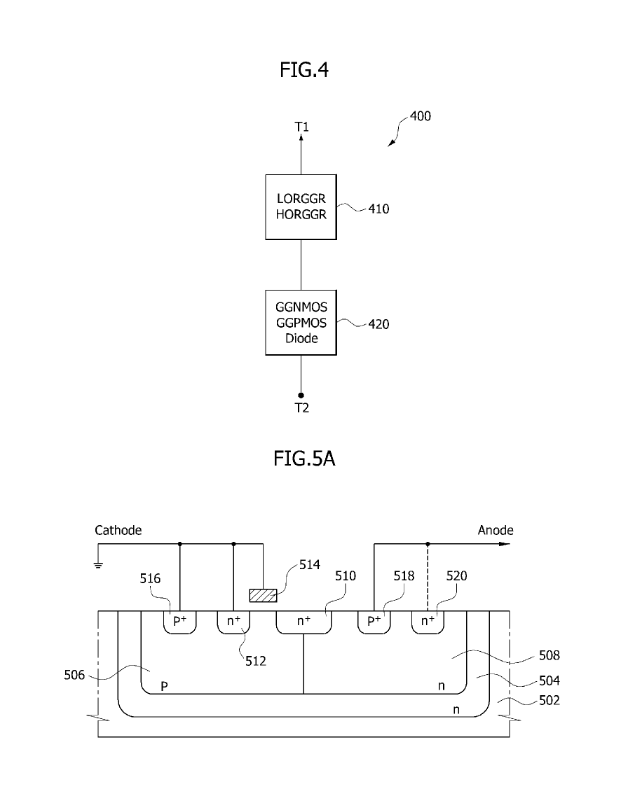

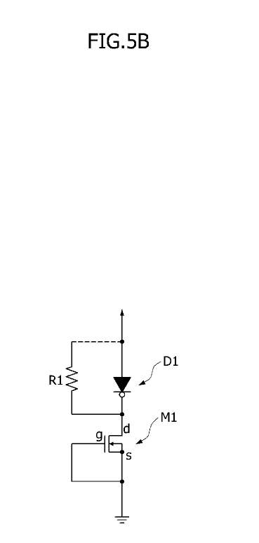

FIG. 4 is a diagram of an ESD protection device in accordance with one exemplary embodiment of the present disclosure;

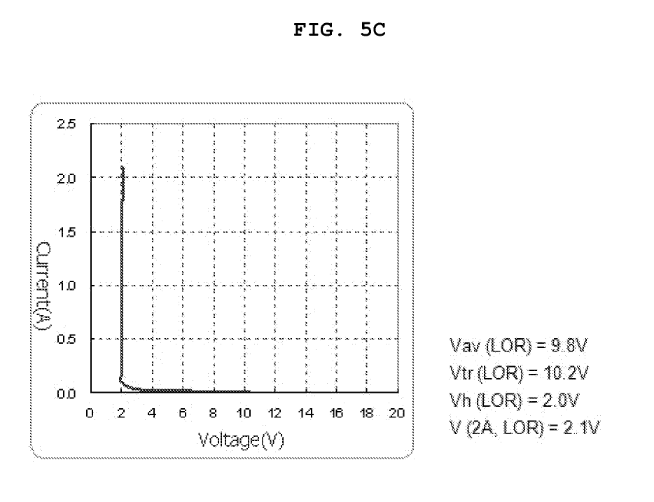

FIG. 5a is a sectional view of an LORGGR included in a first group of electrostatic discharge protection devices of FIG. 4;

FIG. 5b is a circuit diagram of the LORGGR of FIG. 5a;

FIG. 5c is a graphical representation of electrical characteristics of the LORGGR of FIG. 5a;

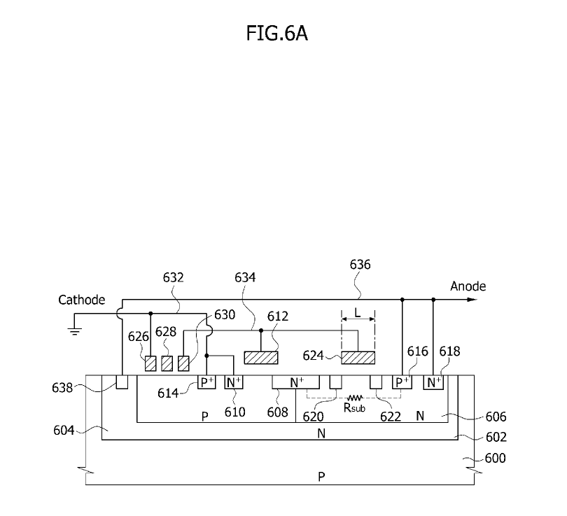

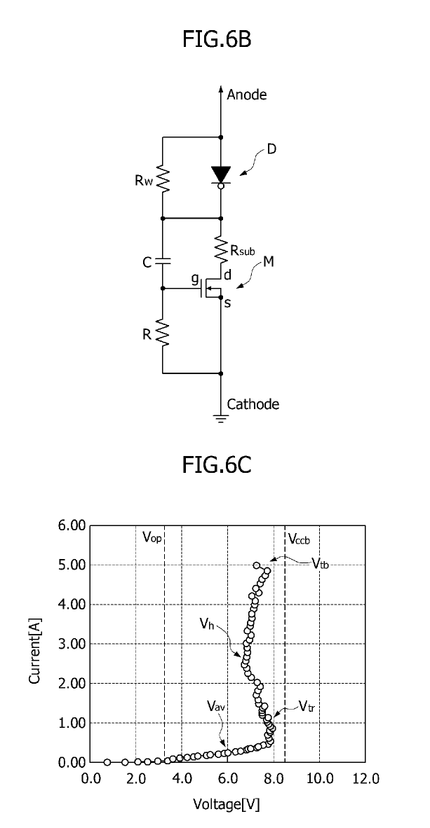

FIG. 6a is a sectional view of one exemplary embodiment of an HORGGR included in the first group of electrostatic discharge protection devices of FIG. 4;

FIG. 6b is a circuit diagram of the HORGGR of FIG. 6a;

FIG. 6c is a graphical representation of electrical characteristics of the HORGGR of FIG. 6a;

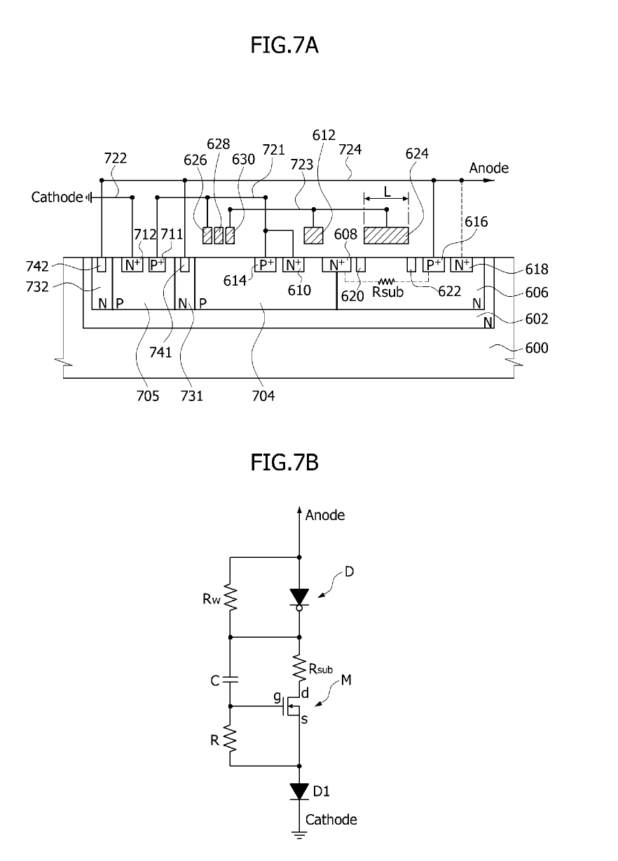

FIG. 7a is a sectional view of another exemplary embodiment of the HORGGR included in a first group of electrostatic discharge protection devices of FIG. 4;

FIG. 7b is a circuit diagram of the HORGGR of FIG. 7a;

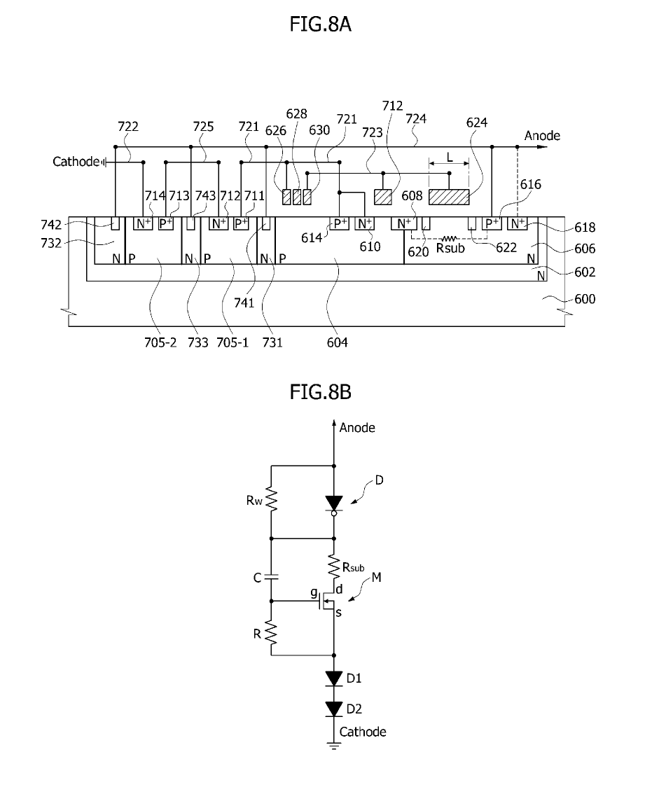

FIG. 8a is a sectional view of a further exemplary embodiment of the HORGGR included in the first group of electrostatic discharge protection devices of FIG. 4;

FIG. 8b is a circuit diagram of the HORGGR of FIG. 8a;

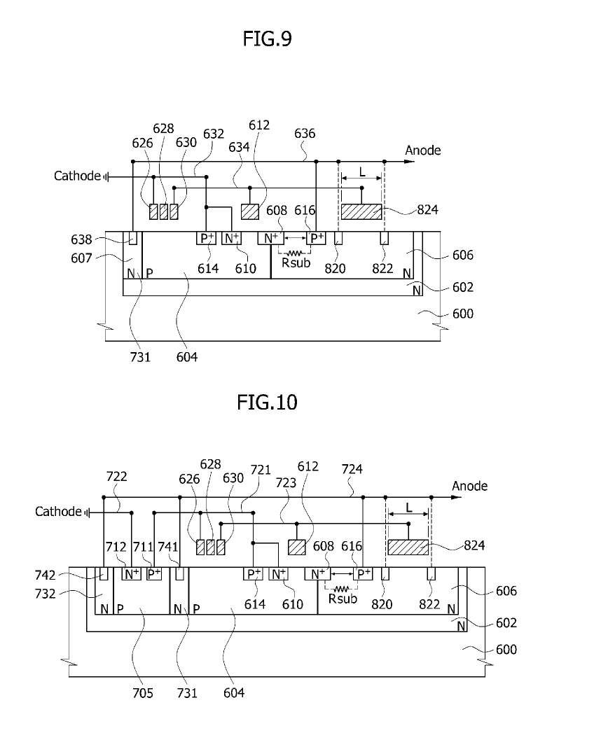

FIGS. 9 to 11 are sectional views of HORGGRs according to other exemplary embodiments of the present disclosure;

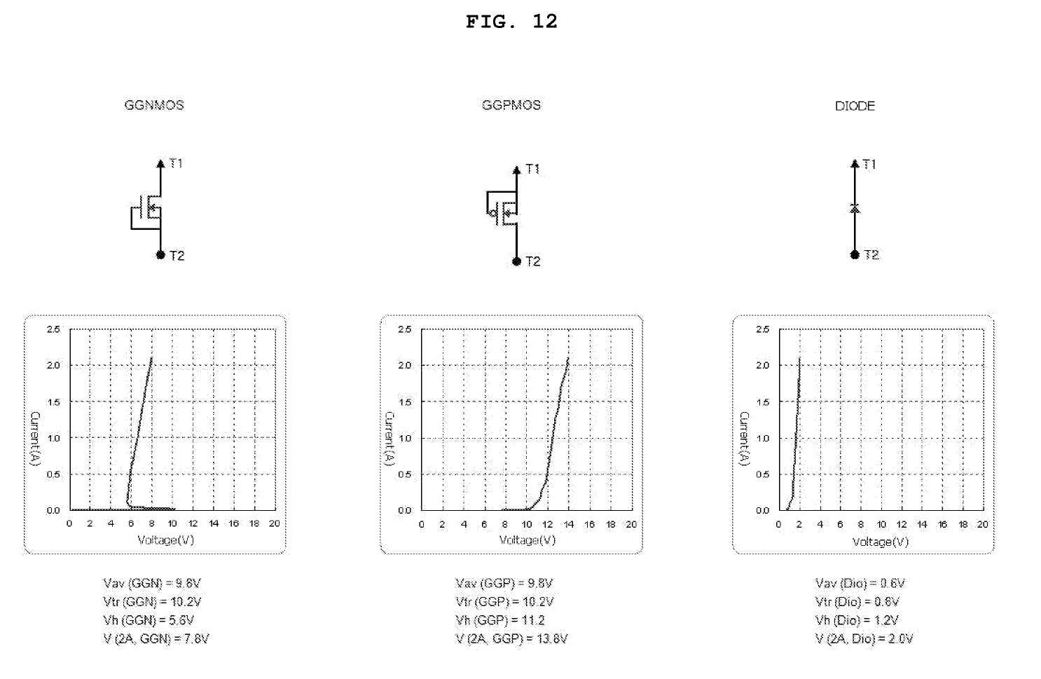

FIG. 12 are circuit diagrams and graphical representations of voltage-current characteristics of a GGNMOS, a GGPMOS and a diode included in a second group of electrostatic discharge protection devices of FIG. 4;

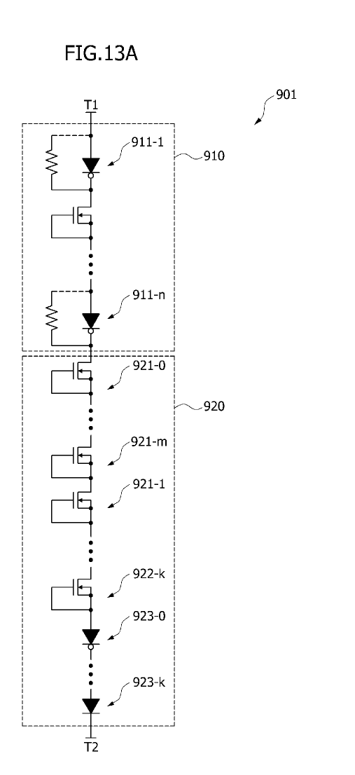

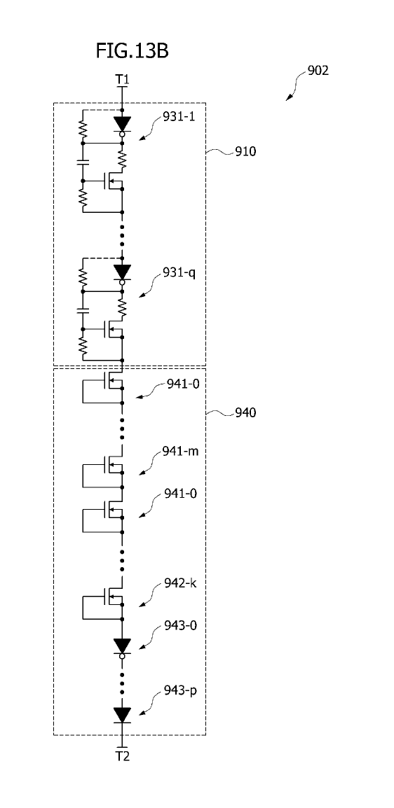

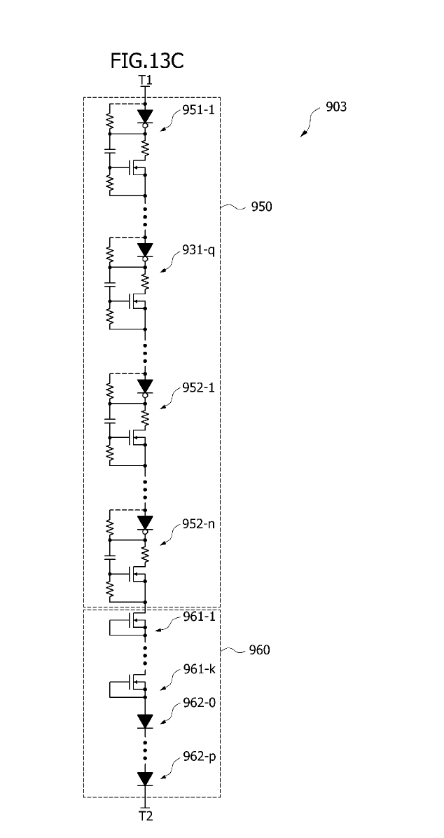

FIGS. 13a to 13c are circuit diagrams of ESD protection devices in accordance with exemplary embodiments of the present disclosure;

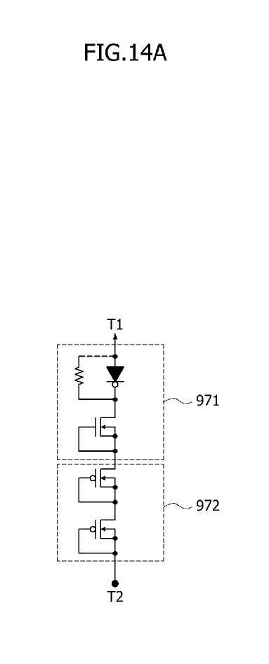

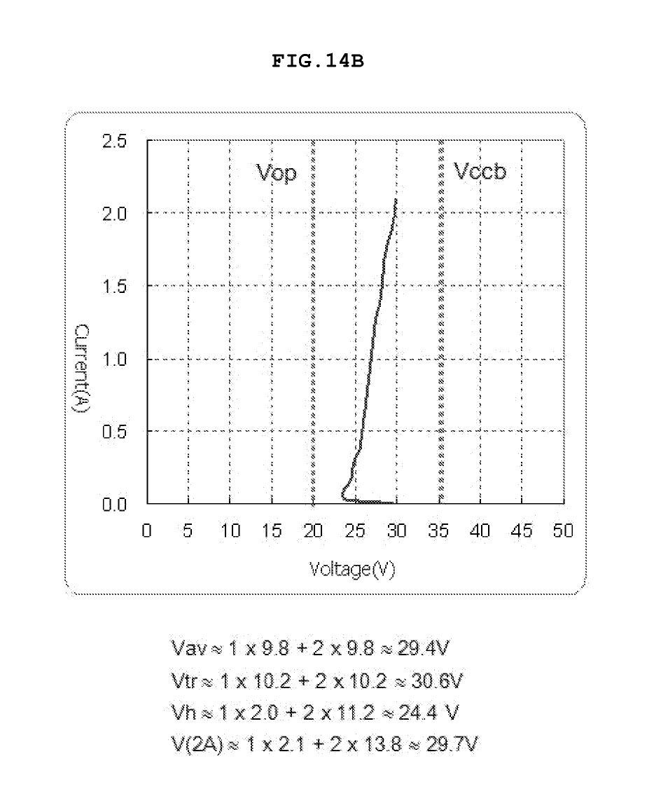

FIG. 14a is a circuit diagram of an ESD protection device in accordance with yet another exemplary embodiment of the present disclosure;

FIG. 14b is a graphical representation of electrical characteristics of the ESD protection device of FIG. 14a;

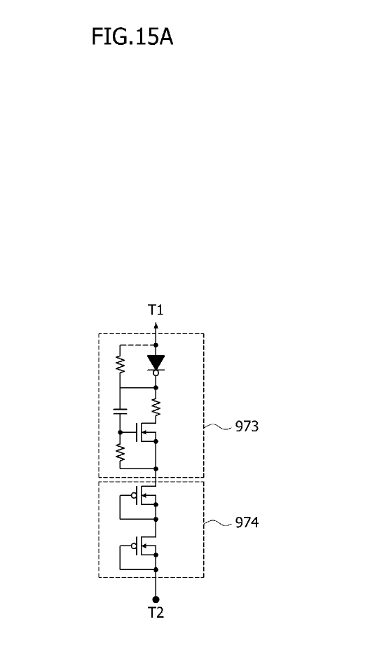

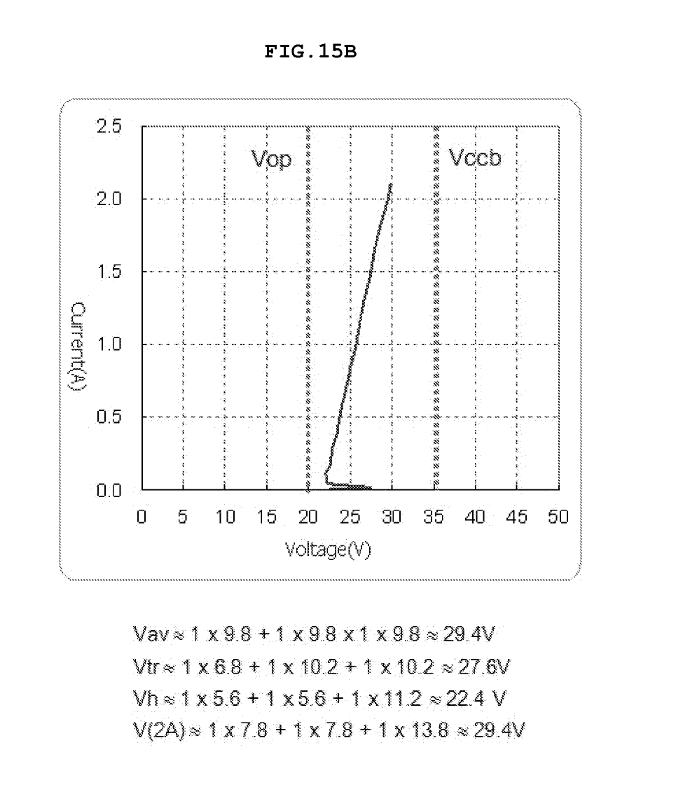

FIG. 15a is a circuit diagram of an ESD protection device in accordance with a further exemplary embodiment of the present disclosure;

FIG. 15b is a graphical representation of electrical characteristics of the ESD protection device of FIG. 15a;

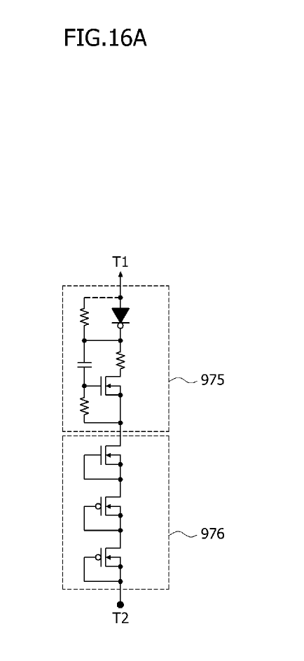

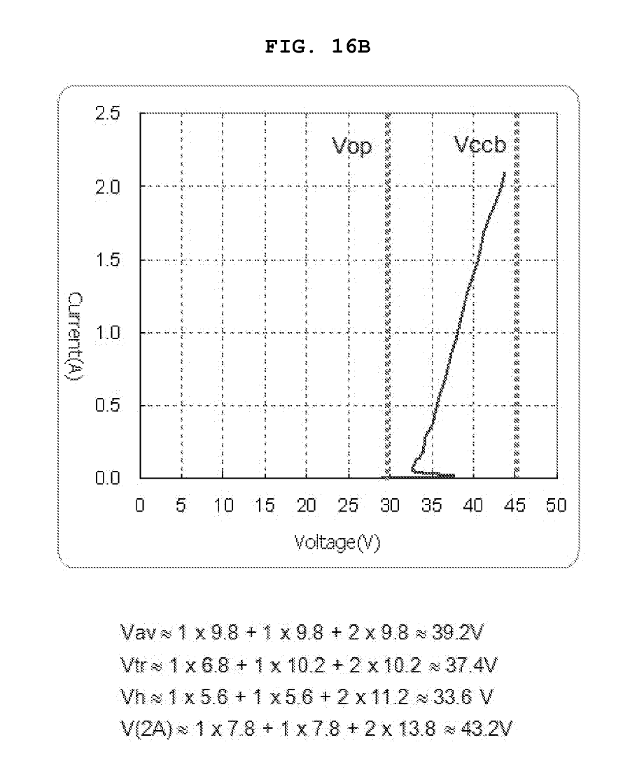

FIG. 16a is a circuit diagram of an ESD protection device in accordance with yet another exemplary embodiment of the present disclosure;

FIG. 16b is a graphical representation of electrical characteristics of the ESD protection device of FIG. 16a;

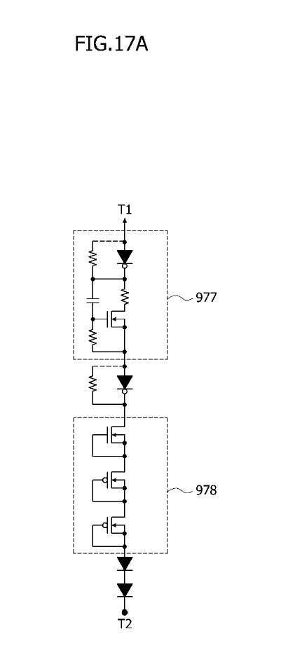

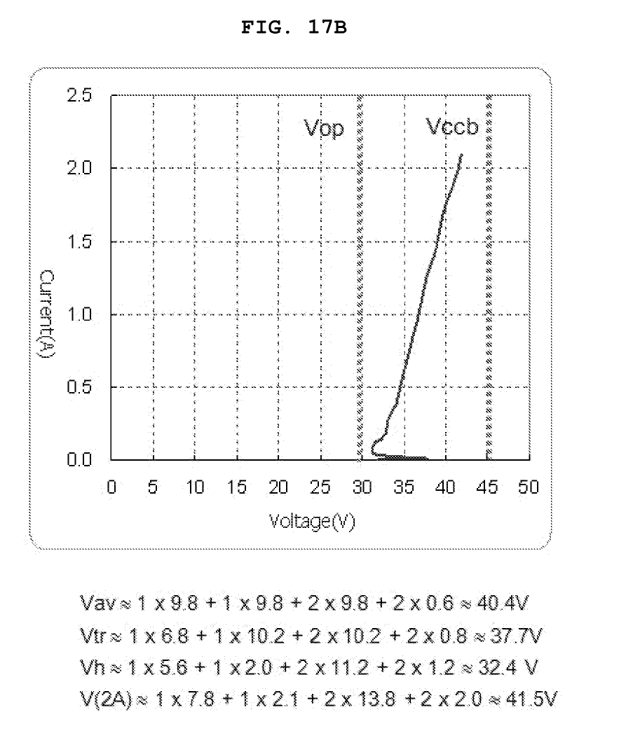

FIG. 17a is a circuit diagram of an ESD protection device in accordance with yet another exemplary embodiment of the present disclosure; and

FIG. 17b is a graphical representation of electrical characteristics of the ESD protection device of FIG. 17a.

### DETAILED DESCRIPTION

Exemplary embodiments will now be described in detail with reference to the accompanying drawings.

FIG. 4 is a diagram of an ESD protection device in accordance with one exemplary embodiment of the present disclosure. Referring to FIG. 4, an ESD protection device 400 includes a first group of electrostatic discharge protection devices 410 and a second group of electrostatic discharge protection devices 420 connected in series to each other between a first terminal T1 and a second terminal T2. The first group of electrostatic discharge protection devices 410 is connected in series to the first terminal T1 and includes at least one of a low on-resistance gate grounded rectifier (LORGGR) and a high on-resistance gate grounded rectifier (HORGGR). The second group of electrostatic discharge protection devices 420 is connected in series to the first group of electrostatic discharge protection devices 410 and the second terminal T2, and includes at least one of a gate grounded NMOS (GGNMOS), a gate grounded PMOS (GGPMOS) and a diode.

FIG. 5a is a sectional view of the LORGGR included in the first group of electrostatic discharge protection devices of FIG. 4. Referring to FIG. 5a, an n−type deep well region 504 is formed in an upper region of a p−type substrate 502. A p−type well region 506 and an n−type well region 508 are formed in upper regions of the n−type deep well region 504, respectively. The p−type well region 506 and the n−type well region 508 are disposed in contact with each other at one side thereof. An n−type drain region 510 is formed at an upper portion of a contact side between the p−type well region 506 and the n−type well region 508. That is, a left portion of the n−type drain region 510 is placed at an upper portion of the p−type well region 506 and a right portion of the n−type drain region 510 is placed at an upper portion of the n−type well region 508. An n−type source region 512 is formed at an upper portion of the p−type well region 506 and is separated from the n−type drain region 510 by a distance corresponding to a channel region. A gate electrode 514 is disposed above the channel region. In one embodiment, the gate electrode 514 is formed of a polysilicon layer. Although not shown in the drawings, a gate insulation layer (not shown) is interposed between the gate electrode 514 and the channel region. A p−type cathode region 516 is formed at an upper portion of the p−type well region 506 and separated a predetermined distance from the n−type source region 512. A p−type anode region 518 and an n−type anode compensation region 520 are formed in an upper region of the n−type well region 508 to be separated from each other. A cathode is connected to ground, and the n−type source region 512, the gate electrode 514 and the p−type cathode region 516 are commonly connected to the cathode. Further, an anode is connected to the p−type anode region 518 and the n−type anode compensation region 520. Alternatively, the n−type anode compensation region 520 may not be connected to the anode.

FIG. 5b is a circuit diagram of the LORGGR of FIG. 5a. Referring to FIG. 5a and FIG. 5b, a MOS transistor M1 is composed of the n−type drain region 510, the n−type source region 512 and the gate electrode layer 514, in which a source (s) and a gate (g) are connected to the cathode and a drain (d) is connected to one end of a resistor R1 in the n−type well region 508 between the n−type drain region 510 and the p−type anode region 518. In the MOS transistor M1, the drain (d) and the one end of resistor R1 are connected to an anode of a diode D1, which is a p-n diode formed of the n−type well region 508 and the p−type anode region 518. The other end of the resistor R1 may be connected to or may not be connected to the cathode or anode of the diode D1 (as indicated by a dotted line in the drawings).

When electrostatic discharge current flows in such an LORGGR with the cathode connected to ground and a positive electrostatic voltage applied to the anode, an NPN parasitic bipolar transistor and a PNP parasitic bipolar transistor are operated to discharge electrostatic current. In particular, the NPN parasitic bipolar transistor and the PNP parasitic bipolar transistor are coupled to each other to operate as a rectifier through which current can smoothly flow. Here, the NPN parasitic bipolar transistor is a parasitic bipolar transistor formed of the n−type anode compensation region 520, the n−type well region 508 and an n-p-n structure of the n−type drain region 510/p−type well region 506/n−type source region 512. Further, the PNP parasitic bipolar transistor is a parasitic bipolar transistor formed of the p−type cathode region 516 and a p-n-p structure of the p−type well region 506/n−type drain region 510, n−type well region 508/p−type anode region 518. When the NPN parasitic bipolar transistor and the PNP parasitic bipolar transistor perform rectifier operation, electrostatic discharge current spreads widely not only on the surface of the device but in the vertical direction, so that a large amount of electrostatic discharge current can be discharged, as compared with the size of the device.

FIG. 5c is a graphical representation of electrical characteristics of the LORGGR of FIG. 5a. As shown in FIG. 5a, the LORGGR has a very wide area path through which current flows, thereby exhibiting low operation resistance characteristics.

FIG. 6a is a sectional view of one exemplary embodiment of an HORGGR included in the first group of electrostatic discharge protection devices of FIG. 4. Referring to FIG. 6a, an n−type deep well region 602 is formed in an upper region of a p−type substrate 600. A p−type well region 604 and an n−type well region 606 are formed in upper regions of the n−type deep well region 602, respectively. The p−type well region 604 and the n−type well region 606 are disposed in contact with each other at one side thereof. An n−type drain region 608 is formed at an upper portion of a contact side between the p−type well region 604 and the n−type well region 606. That is, a left portion of the n−type drain region 608 is placed at an upper portion of the p−type well region 604 and a right portion of the n−type drain region 608 is placed at an upper portion of the n−type well region 606. An n−type source region 610 is formed at an upper portion of the p−type well region 604 and is separated from the n−type drain region 608 by a distance corresponding to a channel region. A gate electrode 612 is disposed above the channel region. In one embodiment, the gate electrode 612 is formed of a polysilicon layer. Although not shown in the drawings, a gate insulation layer (not shown) is interposed between the gate electrode 612 and the channel region. A p−type cathode region 614 is formed at an upper portion of the p−type well region 604 and is separated a predetermined distance from the n−type source region 610.

A p−type anode region 616 and an n−type anode compensation region 618 are formed in an upper region of the n−type well region 606 to be separated from each other. A first impurity region 620 and a second impurity region 622 constituting a capacitor are disposed between the n type drain region 608 and the p−type anode region 616. Both the first and second impurity regions 620 and 622 are n−type conductive regions. A capacitor electrode layer 624 is disposed above the n−type well region 606 between the first impurity region 620 and the second impurity region 622, with a dielectric layer (not shown) disposed between the capacitor electrode layer 624 and the n−type well region 606. In one embodiment, the capacitor electrode layer 624 is formed of a polysilicon layer. The capacitor electrode layer 624 has a length L determined in consideration of desired on-resistance. The on-resistance of the device increases with increasing length L of the capacitor electrode layer 624, that is, with increasing distance between the n−type drain region 608 and the p−type anode region 616.

A plurality of conductive layers 626, 628, 630 is disposed to be insulated from one another on a surface of the p−type well region 604 adjacent the p−type cathode region 614. Although this embodiment is illustrated as including three conductive layers, that is, a first conductive layer 626, a second conductive layer 628, and a third conductive layer 630, it is apparent that the present disclosure is not limited thereto and may include more or less conductive layers than in this embodiment. In one embodiment, the first, second and third conductive layers 626, 628 and 630 are formed of a polysilicon layer. The first conductive layer 626 is disposed at one end of the protection device to be connected to the p−type cathode region 614 and the n−type source region 610 while being connected to a cathode connected to ground through a first wire 632. The third conductive layer 630 is disposed at the other end of the protection device and is connected to the gate electrode layer 612 and the capacitor electrode layer 624 through a second wire 634. With this wiring structure, the first conductive layer 626, the second conductive layer 628 and the third conductive layer 630 are subjected to mutual coupling under predetermined conditions, for example, under a condition in which voltage is applied to both ends. An anode is connected to an impurity region 638, the p−type anode region 616 and the n−type anode compensation region 618, which are separated from the p−type well region 604, through a third wire 636. In some embodiments, the third wire 636 is not connected to the n−type anode compensation region 618.

FIG. 6b is a circuit diagram of the HORGGR of FIG. 6a. Referring to FIGS. 6a and 6b, an MOS transistor M is composed of the n−type drain region 608, the n−type source region 610 and the gate electrode layer 612, in which a source (s) is connected to the cathode and a drain (d) is connected to one end of a resistor R_{sub} in the n−type well region 606 between the n−type drain region 608 and the p−type anode region 616. Further, a gate (g) is connected to one end of a capacitor C while being connected to one end of a coupling resistor R. Here, the capacitor C is composed of the capacitor electrode layer 624, the first impurity region 620 and the second impurity region 622, and the coupling resistor R is composed of the first conductive layer 626, the second conductive layer 628 and the third conductive layer 630 separated from one another. Thus, the gate of the MOS transistor M is connected to the capacitor electrode layer 624 and the third conductive layer 630. The other end of the capacitor(C) is connected to the other end of the resistor R_{sub}, that is, one end of a resistor Rw in the n−type well region 606 is connected to the anode. One end of each of the resistor R_{sub} and the resistor Rw is connected to an anode of a diode D. Here, the diode D is a p-n diode composed of the n−type well region 606 and the p−type anode region 616. The other end of the resistor Rw may be connected to or may not be connected to the cathode or anode of the diode D (indicated by a dotted line in the drawings).

When electrostatic discharge current flows in such an HORGGR with the cathode connected to ground and a positive electrostatic voltage applied to the anode, an NPN parasitic bipolar transistor and a PNP parasitic bipolar transistor are operated to discharge electrostatic current. In particular, the NPN parasitic bipolar transistor and the PNP parasitic bipolar transistor are coupled to each other to operate as a rectifier through which current can smoothly flow. Here, the NPN parasitic bipolar transistor is a parasitic bipolar transistor formed of the n−type anode compensation region 618, the n−type well region 606 and an n-p-n structure of the n−type drain region 608/p−type well region 604/n−type source region 610. Further, the PNP parasitic bipolar transistor is a parasitic bipolar transistor formed of the p−type cathode region 614 and a p-n-p structure of the p−type well region 604/n−type drain region 608, n−type well region 606/p−type anode region 616. When the NPN parasitic bipolar transistor and the PNP parasitic bipolar transistor perform rectifier operation, electrostatic discharge current spreads widely not only on the surface of the device but in the vertical direction, so that a large amount of electrostatic discharge current can be discharged, as compared with the size of the device.

Particularly, the gate (g) of the MOS transistor M (gate electrode layer 612 of FIG. 6) is coupled to the anode via the capacitor electrode layer 624 and is connected to the cathode through the resistor R. Thus, an RC coupling structure is formed between the anode and the cathode, so that the MOS transistor M is operated at low voltage, thereby allowing quick operation of the NPN parasitic bipolar transistor at low voltage. Further, the capacitor C is disposed between the n−type drain region 608 and the p−type anode region 616, so that the distance and resistance R_{sub} between the n−type drain region 608 and the p−type anode region 616 increase, thereby providing an effect of increasing on-resistance between the anode and each of the impurity regions. As such, since the on-resistance between the anode and each of the impurity regions is high, the voltage between both ends of the ESD protection device is maintained at a constant level instead of being significantly reduced during actual rectifier operation. Furthermore, when the first impurity region 620 and the n−type anode compensation region 618 constituting the capacitor C are not connected to each other, on-resistance is further increased.

FIG. 6c is a graphical representation of electrical characteristics of the HORGGR of FIG. 6a. Referring to FIG. 6c, the HORGGR has the following characteristics. First, during normal operation of a microchip, the avalanche breakdown voltage Vav and the triggering voltage Vtr of the ESD protection device are greater than the operating voltage Vop of the microchip. Second, when the microchip is subjected to electrostatic discharge stress, the ESD protection device starts to operate at a voltage much lower than the core circuit breakdown voltage Vccb of the microchip. Thus, it is possible to provide fundamental prevention of electrostatic discharge current from flowing into the core circuit and causing breakdown of the core circuit when induced in the microchip. Thirdly, the snapback holding voltage Vh of the ESD protection device is sufficiently greater than the operating voltage Vop of the microchip. Accordingly, the ESD protection device prevents a latch-up phenomenon during normal operation of the microchip. Fourthly, the thermal breakdown voltage Vtb of the ESD protection device is substantially similar to the triggering voltage Vtr thereof. Thus, when a multi-finger structure is adopted, the respective fingers may operate uniformly. Fifthly, the ESD protection device according to this embodiment exhibits an excellent level of current immunity per unit size with respect to electrostatic discharge current. For example, the ESD protection device according to this embodiment may process about two to three times more electrostatic discharge current than a GGNMOS with the same layout area as that of the ESD protection device.

FIG. 7a is a sectional view of another exemplary embodiment of the HORGGR included in the first group of electrostatic discharge protection devices 410 of FIG. 4, and FIG. 7b is a circuit diagram of the HORGGR of FIG. 7a. In FIGS. 7a and 7b, the same elements are indicated by the same reference numerals as those of FIGS. 6a and 6b, and descriptions thereof will thus be omitted. Referring to FIGS. 7a and 7b, the HORGGR according to this embodiment is distinguished from the HORGGR of FIG. 6 in that a p-n diode D1 is disposed between a cathode and a MOS transistor M composed of the n−type drain region 608, the n−type source region 610 and the gate electrode layer 612. Specifically, a p−type well region 705 is disposed adjacent a p−type well region 704, one side of which is in contact with an n−type well region 606, and a p−type anode junction region 711 and an n−type cathode junction region 712 constituting the p-n diode D1 are formed in the p−type well region 705. N-type well regions 731, 732 are disposed at opposite sides of the p−type well region 705 with the p-n diode D1 formed therein, and are respectively provided with impurity regions 741, 742 for wire connection.

In this state, the p−type anode junction region 711 of the p-n diode D1, a first conductive layer 626 of a coupling resistor R, the p−type cathode region 614, and the n−type source region 610 are connected to one another through a first wire 721. The n−type cathode junction region 712 of the p-n diode D1 is connected to the cathode through a second wire 722. In this connection structure, the anode of the p-n diode D1 is connected to both a source (s) of the MOS transistor M and one end of the coupling resistor R. The third conductive layer 630 of the coupling resistor R, the gate electrode layer 612, and the capacitor electrode layer 624 are connected to each other through a third wire 723. Further, the impurity regions 741, 742, the p−type anode region 616 and the n−type anode compensation region 618 are connected to the anode through a fourth wire 724. Here, the n−type anode compensation region 618 may not be connected to the fourth wire 724 (indicated by a dotted line in the drawing).

The ESD protection device of this embodiment further increases on-resistance by the p-n diode D1 for forward operation serially connected to the MOS transistor M. Upon application of electrostatic discharge current, the p-n diode D1 performs forward operation together with rectifier operation of the parasitic bipolar transistors, thereby causing voltage increase proportional to the amount of current passing therethrough by the diode forward operation in which the ESD protection device does not exhibit any snapback characteristic, instead of the rectifier operation in which the ESD protection device exhibits the snapback characteristic. Accordingly, it is possible for the ESD protection device to further increase on-resistance and snapback holding voltage Vh.

FIG. 8a is a sectional view of a further exemplary embodiment of the HORGGR included in the first group of electrostatic discharge protection devices of FIG. 4, and FIG. 8b is a circuit diagram of the HORGGR of FIG. 8a. In FIGS. 8a and 8b, the same elements are indicated by the same reference numerals as those of FIGS. 6a and 6b, and descriptions thereof will thus be omitted. Referring to FIGS. 8a and 8b, the HORGGR according to this embodiment is distinguished from the HORGGR of FIG. 6a in that the device of this embodiment is provided with twp p-n diodes. Specifically, a first p-n diode D1 composed of a first p−type anode junction region 711 and a first n−type cathode junction region 712 is disposed in a p−type well region 705-1, and a second p-n diode D2 composed of a second p−type anode junction region 713 and a second n−type cathode junction region 714 is disposed in a p−type well region 705-2. An n−type well region 733 is disposed between the p−type well region 705-1 having the first p-n diode D1 therein and the p−type well region 705-1 having the second p-n diode D2 therein, and includes an impurity region 743 for wire connection.

To allow forward operation of the first and second p-n diodes D1, D2, a cathode is connected to the second n−type cathode junction region 714 of the second p-n diode D2 via a second wire 722, and the first p−type anode junction region 711 of the first p-n diode D1 is connected to the first conductive layer 626 of the coupling resistor R, the p−type anode region 614 and the n−type source region 610 via a first wire 721. Further, the first n−type cathode junction region 712 of the first p-n diode D1 is connected to the second p−type anode junction region 713 of the second p-n diode D2 via a fifth wire 725. In the HORGGR according to this embodiment, the two p-n diodes D1, D2 are arranged to be connected in series between the MOS transistor M and the cathode to perform forward operation, so that the ESD protection device exhibits higher on-resistance and snapback holding voltage Vh than the HORGGR illustrated with reference to FIG. 6a.

FIG. 9 is a sectional view of an HORGGR according to yet another exemplary embodiment. In FIG. 9, the same elements are indicated by the same reference numerals as those of FIG. 6a, and descriptions thereof will thus be omitted. For reference, a circuit diagram of the HORGGR shown in FIG. 9 is the same as that shown in FIG. 6b. Referring to FIG. 9, in the HORGGR according to this embodiment, a p−type anode region 616 is disposed adjacent an n−type drain region 608, and a first impurity region 820, a second impurity region 822 and a capacitor electrode layer 824 are disposed to constitute a capacitor C outside the p−type anode region 616. Therefore, when the capacitor electrode layer 824 is formed to a sufficiently long length L in order to provide sufficient on-resistance, the resistance R_{sub} does not increase due to increase of the length L of the capacitor electrode layer 824. Upon rectifier operation of the device, since the on-resistance increases proportional not only to the length L of the capacitor electrode layer 824 but also to the resistance R_{sub}, the on-resistance excessively increases when the length L and the resistance R_{sub} of the capacitor electrode layer 824 increase at the same time, thereby making it difficult to properly process electrostatic discharge current. In the HORGGR according to this embodiment, however, since the length L of the capacitor electrode layer 824 may be adjusted as needed without increasing the resistance R_{sub}, it is possible to control the on-resistance of the device to a desired level.

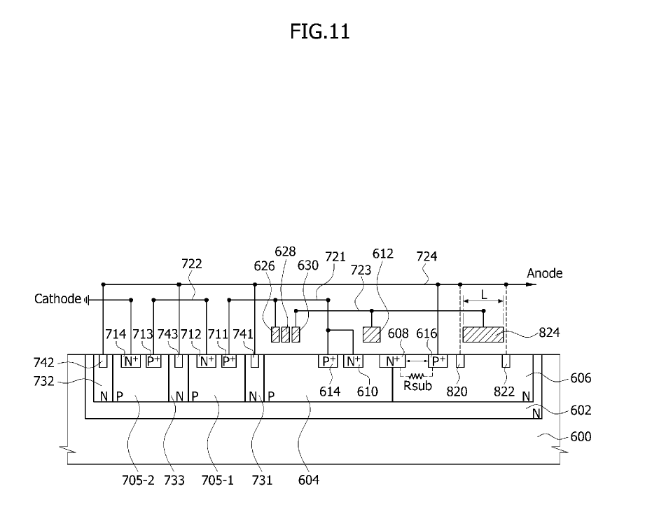

FIG. 10 is a sectional view of an HORGGR according to yet another exemplary embodiment. In FIG. 10, the same elements are indicated by the same reference numerals as those of FIG. 7a, and descriptions thereof will thus be omitted. For reference, a circuit diagram of the HORGGR shown in FIG. 10 is the same as that shown in FIG. 7b. Referring to FIG. 10, in the HORGGR according to this embodiment, a first impurity region 820, a second impurity region 822 and a capacitor electrode layer 824 constituting a capacitor are disposed outside the p−type anode region 616 to increase the length L of the capacitor electrode layer 824 without increasing the resistance R_{sub}. Further, as described with reference to FIG. 6a, a p-n diode for forward operation is disposed between the MOS transistor and the cathode, whereby the HORGGR may exhibit high on-resistance and snapback holding voltage Vh.

FIG. 11 is a sectional view of an HORGGR according to yet another exemplary embodiment. In FIG. 11, the same elements are indicated by the same reference numerals as those of FIG. 7a, and descriptions thereof will thus be omitted. For reference, a circuit diagram of the HORGGR shown in FIG. 11 is the same as that shown in FIG. 8b. Referring to FIG. 11, in the HORGGR according to this embodiment, a first impurity region 820, a second impurity region 822 and a capacitor electrode layer 824 constituting a capacitor are disposed outside a p−type anode region to increase the length L of the capacitor electrode layer 824 without increasing the resistance R_{sub}. Further, as described with reference to FIG. 8a, first and second p-n diodes D1, D2 for forward operation are disposed between the MOS transistor and the cathode, so that the HORGGR exhibits high on-resistance and snapback holding voltage Vh.

FIG. 12 are circuit diagrams and graphical representations of voltage-current characteristics of a GGNMOS, a GGPMOS and a diode included in the second group of electrostatic discharge protection devices of FIG. 4. The GGNMOS, GGPMOS and diode are applied to low voltage, for example, a rated voltage of about 1.8V or less, or medium voltage, for example, a rated voltage of about 2.5V to 6.0V, and each exhibits stable electrical characteristics, as shown in FIG. 12. The GGNMOS exhibits a strong snapback phenomenon wherein voltage is reduced upon increase in electric current therein after NPN-type BJT operation is triggered at a relatively high voltage. For the GGPMOS, the NPN-type BJT operation is triggered at a voltage substantially similar to that of the GGNMOS and snapback characteristics are not exhibited. For the diode, forward operation is triggered at a very low voltage and an increase in voltage according to the amount of current is insignificant. The diode does not exhibit snapback characteristics, either. The characteristic variables of the GGNMOS, GGPMOS and diode, such as triggering voltage Vtr, snapback holding voltage Vh and thermal breakdown voltage Vtb, are exhibited as different absolute values according to processes, and each of the values shown in FIG. 12 is provided as a general example and may have a predetermined level of deviation.

FIGS. 13a to 13c are circuit diagrams of ESD protection devices in accordance with exemplary embodiments. First, referring to FIG. 13a, an ESD protection device 901 according to one exemplary embodiment includes a first group of electrostatic discharge protection devices 910 connected in series to a first terminal T1 and a second group of electrostatic discharge protection devices 920 connected in series to the first group of electrostatic discharge protection devices 910 and a second terminal T2. The first group of electrostatic discharge protection devices 910 is composed of n LORGGRs (911-1, . . . , 911-n) connected to each other in series. The second group of electrostatic discharge protection devices 920 is composed of (m+1) GGNMOSs (921-0, . . . , 921-m), k GGPMOSs (922-1, . . . , 922-k), and (k+1) diodes (923-0, . . . , 923-k) connected to each other in series. The ESD protection device according to this embodiment may be formed in various ways and exhibit various characteristics by suitably adjusting the kind and number of the ESD protection devices constituting the first group of electrostatic discharge protection devices 910 and the kind and number of the ESD protection devices constituting the second group of electrostatic discharge protection devices 920.

Next, referring to FIG. 13b, an ESD protection device 902 according to another exemplary embodiment includes a first group of electrostatic discharge protection devices 930 connected in series to a first terminal T1 and a second group of electrostatic discharge protection devices 940 connected in series to the first group of electrostatic discharge protection devices 930 and a second terminal T2. The first group of electrostatic discharge protection devices 930 is composed of q HORGGRs (931-1, . . . , 931-q) connected in series to each other. The second group of electrostatic discharge protection devices 940 is composed of (m+1) GGNMOSs (941-0, . . . , 941-m), k+1 GGPMOSs (942-0, . . . , 942-k), and (p+1) diodes (943-0, . . . , 943-p) connected in series to each other. The ESD protection device 902 according to this embodiment may also be formed in various ways and exhibit various characteristics by suitably adjusting the kind and number of the ESD protection devices constituting the first group of electrostatic discharge protection devices 930 and the kind and number of the ESD protection devices constituting the second group of electrostatic discharge protection devices 940.

Next, referring to FIG. 13c, an ESD protection device 903 according to a further exemplary embodiment includes a first group of electrostatic discharge protection devices 950 connected in series to a first terminal T1 and a second group of electrostatic discharge protection devices 960 connected in series to the first group of electrostatic discharge protection devices 950 and a second terminal T2. The first group of electrostatic discharge protection devices 950 is composed of q LORGGRs (951-1, . . . , 951-q) and n HORGGRs (952-1, . . . , 952-n) connected in series to each other. The second group of electrostatic discharge protection devices 960 is composed of k GGNMOSs (961-1, . . . , 961-k) and (p+1) diodes (962-0, . . . , 962-p) connected in series to each other. The ESD protection device 903 according to this embodiment may also be formed in various ways and exhibit various characteristics by suitably adjusting the kind and number of the ESD protection devices constituting the first group of electrostatic discharge protection devices 950 and the kind and number of the ESD protection devices constituting the second group of electrostatic discharge protection devices 960.

FIG. 14a is a circuit diagram of an ESD protection device in accordance with yet another exemplary embodiment, and FIG. 14b is a graphical representation of electrical characteristics of the ESD protection device of FIG. 14a. Referring to FIGS. 14a and 14b, the ESD protection device according to this embodiment is realized to perform optimized operation at an operating voltage of 20V and a core circuit breakdown voltage of 35V, in which a first group of electrostatic discharge protection devices 971 is composed of a single LORGGR and a second group of electrostatic discharge protection devices 972 is composed of two GGPMOSs. In this case, characteristic variables of the ESD protection device, particularly, total avalanche voltage (Vav(Op)) in normal operation, the total triggering voltage (Vtr(ESD)) upon inflow of electrostatic current, the total snapback holding voltage (Vh(Tot)), and the total operating voltage (V(2 A, Tot)) upon inflow of an electric current of 2 A, may be calculated as follows:

Vav(Op)≈n×Vav(LOR)+k×Vav(GGP)≈×9.8+2×9.8≈29.4V>20V,

Vtr(ESD)≈n×Vtr(LOR)+k×Vtr(GGP)≈×10.2+2×10.2≈30.6V<35V,

Vh(Tot)≈n×Vh(LOR)+k×Vh(GGP)≈1×2.0+2×11.2≈24.4V>20V, and

V(2A,Tot)≈n×V(2A,LOR)+k×V(2A,GGP)≈1×2.1+2×13.8≈29.7V<35V,

where n represents the number of LORGGRs and k represents the number of GGPMOSs.

That is, as described above with reference to FIG. 1, the ESD protection device according to this embodiment satisfies all requirements for the ESD protection device. Accordingly, the ESD protection device is one example of the ESD protection device optimized for an operating voltage of 20V and a core circuit breakdown voltage of 35V.

FIG. 15a is a circuit diagram of an ESD protection device in accordance with a further exemplary embodiment, and FIG. 15b is a graphical representation of electrical characteristics of the ESD protection device of FIG. 15a. Referring to FIGS. 15a and 15b, the ESD protection device according to this embodiment is also realized to perform optimized operation at an operating voltage of 20V and a core circuit breakdown voltage of 35V, in which a first group of electrostatic discharge protection devices 973 is composed of a single HORGGR and a second group of electrostatic discharge protection devices 974 is composed of a single GGNMOS and a single GGPMOS. In this case, characteristic variables of the ESD protection device, particularly, total avalanche voltage (Vav(Op)) in normal operation, the total triggering voltage (Vtr(ESD)) upon inflow of electrostatic current, the total snapback holding voltage (Vh(Tot)), and the total operating voltage (V(2 A, Tot)) upon inflow of an electric current of 2 A, may be calculated as follows:

Vav(Op)≈q×Vav(HOR)+m×Vav(GGN)+k×Vav(GGP)≈1×9.8+1×9.8+1×9.8≈29.4V>20V,

Vtr(ESD)≈q×Vtr(HOR)+m×Vtr(GGN)+k×Vtr(GGP)≈1×6.8+1×10.2+1×10.2≈27.6V<35V,

Vh(Tot)≈q×Vh(HOR)+m×Vh(GGN)+k×Vh(GGP)≈1×5.6+1×2.6+1×11.2≈22.4V>20V,

and

V(2A,Tot)≈q×V(2A,LOR)+m×V(2A,GGN)+k×V(2A,GGP)≈1×7.8+1×7.8+1×13.8≈29.4V<35V,

where q represents the number of HORGGRs, m represents the number of GGNMOSs, and k represents the number of GGPMOSs.

That is, as described above with reference to FIG. 1, the ESD protection device according to this embodiment satisfies all requirements for the ESD protection device. Accordingly, the ESD protection device is another example of the ESD protection device optimized for an operating voltage of 20V and a core circuit breakdown voltage of 35V.

FIG. 16a is a circuit diagram of an ESD protection device in accordance with yet another exemplary embodiment, and FIG. 16b is a graphical representation of electrical characteristics of the ESD protection device of FIG. 16a. Referring to FIGS. 16a and 16b, the ESD protection device according to this embodiment is realized to perform optimized operation at an operating voltage of 30V and a core circuit breakdown voltage of 45V, in which a first group of electrostatic discharge protection devices 975 is composed of a single HORGGR and a second group of electrostatic discharge protection devices 976 is composed of a single GGNMOS and two GGPMOSs. In this case, characteristic variables of the ESD protection device, particularly, total avalanche voltage (Vav(Op)) in normal operation, total triggering voltage (Vtr(ESD)) upon inflow of electrostatic current, total snapback holding voltage (Vh(Tot)), and total operating voltage (V(2 A, Tot)) upon inflow of an electric current of 2 A, may be calculated as follows:

Vav(Op)≈q×Vav(HOR)+m×Vav(GGN)+k×Vav(GGP)≈1×9.8+1×9.8+2×9.8≈39.2V>30V,

Vtr(ESD)≈q×Vtr(HOR)+m×Vtr(GGN)+k×Vtr(GGP)≈1×6.8+1×10.2+2×10.2≈37.4V<45V,

Vh(Tot)≈q×Vh(HOR)+m×Vh(GGN)+k×Vh(GGP)≈1×5.6+1×2.6+2×11.2≈33.6V>30V, and

V(2A,Tot)≈q×V(2A,HOR)+m×V(2A,GGN)+k×V(2A,GGP)≈1×7.8+1×7.8+2×13.8≈43.2V<45V,

where q represents the number of HORGGRs, m represents the number of GGNMOSs, and k represents the number of GGPMOSs.

That is, as described above with reference to FIG. 1, the ESD protection device according to this embodiment satisfies all requirements for the ESD protection device. Accordingly, the ESD protection device is one example of the ESD protection device optimized at an operating voltage of 30V and a core circuit breakdown voltage of 45V.

FIG. 17a is a circuit diagram of an ESD protection device in accordance with yet another exemplary embodiment of the present disclosure, and FIG. 17b is a graphical representation of electrical characteristics of the ESD protection device of FIG. 17a. Referring to FIGS. 17a and 17b, the ESD protection device according to this embodiment is realized to perform optimized operation at an operating voltage of 30V and a core circuit breakdown voltage of 45V, in which a first group of electrostatic discharge protection devices 977 is composed of a single HORGGR and a single LORGGR and a second group of electrostatic discharge protection devices 978 is composed of two GGPMOSs and two diodes. In this case, characteristic variables of the ESD protection device, particularly, total avalanche voltage (Vav(Op)) in normal operation, total triggering voltage (Vtr(ESD)) upon inflow of electrostatic current, total snapback holding voltage (Vh(Tot)), and total operating voltage (V(2 A, Tot)) upon inflow of an electric current of 2 A, may be calculated as follows:

Vav(Op)≈q×Vav(HOR)+n×Vav(LOR)+k×Vav(GGP)+p×Vav(Dio)≈1×9.8+1×9.8+2×9.8+2×0.6≈40.4V>30V,

Vtr(ESD)≈q×Vtr(HOR)+n×Vtr(LOR)+k×Vtr(GGP)+p×Vtr(Dio)≈1×6.8+1×10.2+2×10.2+2×0.8≈37.7V<45V,

Vh(Tot)≈q×Vh(HOR)+n×Vh(LOR)+k×Vh(GGP)+p×Vh(Dio)≈1×5.6+1×2.0+2×11.2+2×1.2≈33.6V>30V, and

V(2A,Tot)≈q×V(2A,HOR)+n×V(2A,LOR)+k×V(2A,GGP)+p×V(2A,Dio)≈1×7.8+1×2.1+2×13.8+2×2.0≈43.2V<45V,

where q represents the number of HORGGRs, n represents the number of LORGGRs, and p represents the number of diodes.

That is, as described above with reference to FIG. 1, the ESD protection device according to this embodiment satisfies all requirements for the ESD protection device. Accordingly, the ESD protection device is another example of the ESD protection device optimized for an operating voltage of 30V and a core circuit breakdown voltage of 45V.

As such, according to the exemplary embodiments of the present disclosure, the ESD protection devices may have high avalanche breakdown voltage and cope with a large amount of electrostatic discharge current while achieving uniform operation of respective fingers in a multi-finger structure.

Although some embodiments have been provided to illustrate the present disclosure, it should be understood that these embodiments are given by way of illustration only, and that various modifications, variations, and alterations can be made without departing from the spirit and scope of the present disclosure. The scope of the present disclosure should be limited only by the accompanying claims and equivalents thereof.

What is claimed is:

1. An electrostatic discharge (ESD) protection device, comprising:
a first group of electrostatic discharge protection devices connected in series to a first terminal and including at least one of an LORGGR and an HORGGR; and
a second group of electrostatic discharge protection devices connected in series to the first group of electrostatic discharge protection devices and a second terminal, and including at least one of a GGNMOS, a GGPMOS and a diode.

2. The ESD protection device according to claim 1, wherein the HORGGR comprises:
a p−type well region and an n−type well region disposed in contact with each other at one side thereof;
an n−type drain region disposed on a contact side between the p−type well region and the n−type well region;
an n−type source region disposed in the p−type well region to be separated from the n−type drain region by a distance corresponding to a channel region;
a gate electrode layer disposed on the channel region with a gate insulation layer interposed therebetween;
a p−type anode region disposed inside the n−type well region;
a plurality of conductive layers for a coupling resistor disposed above the p−type well region and separated from each other;
a capacitor including an impurity region disposed inside the n−type well region and a capacitor electrode layer disposed above the n−type well region with an insulation layer interposed therebetween;
a first wire connecting the n−type source region and a conductive layer disposed at one end of the device among the plurality of conductive layers to a cathode;
a second wire connecting a conductive layer disposed at the other end of the device among the plurality of conductive layers, the gate electrode layer, and the capacitor electrode layer to one another; and
a third wire connecting the p−type anode region to an anode.

3. The ESD protection device according to claim 2, wherein the capacitor is disposed between the n−type drain region and the p−type anode region.

4. The ESD protection device according to claim 3, wherein the capacitor is disposed at one side of the p−type anode region opposite the n−type drain region.

5. The ESD protection device according to claim 2, further comprising:
a p-n diode comprising a p−type anode junction region connected to the n−type source region and an n−type cathode junction region connected to the cathode.

6. The ESD protection device according to claim 5, wherein a plurality of p-n diodes each including the p−type anode junction region connected to the n−type source region and the n−type cathode junction region connected to the cathode is serially arranged.

7. The ESD protection device according to claim 1, wherein the HORGGR comprises:
a MOS transistor having a drain connected to an anode and a source connected to a cathode;
a capacitor connected at one end thereof to a gate of the MOS transistor and connected at the other end thereof to the anode; and
a resistor connected at one end thereof to the gate of the MOS transistor and the one end of the capacitor, and connected at the other end thereof to the cathode.

8. The ESD protection device according to claim 7, further comprising: a diode for forward operation between the source of the MOS transistor and the cathode.
